(19) United States
(12) Patent Application Publication
(10) Pub. No.: US 2009/0087783 A1
(43) Pub. Date: Apr. 2, 2009

(54) Original plate for lithography, and resin composition for photosensitive layer in original plate for lithography

(75) Inventors: Tomoya Terauchi, Aichi (JP); Yuji Inatomi, Chiba (JP); Takayuki Sanada, Chiba (JP); Hiroyoshi Kurihara, Aichi (JP); Akihiro Koide, Chiba (JP)

Correspondence Address: BUCHANAN, INGERSOLL & ROONEY PC, POST OFFICE BOX 1404, ALEXANDRIA, VA, 22313-1404, US

(73) Assignee: Mitsui Chemicals, Inc., Minato-ku (JP)

(21) Appl. No.: 11/991,313

(22) PCT Filed: Jul. 28, 2006
(86) PCT No.: PCT/JP2006/315045

§ 371 Date: Feb. 29, 2008

(30) Foreign Application Priority Data
Aug. 30, 2005 (JP) 2005-248662

(51) Int. Cl. G03F 7/028; G03F 7/004

(52) U.S. Cl. 430/283.1; 430/270.1

(57) ABSTRACT

The present invention provides a precursor that may provide a lithographic printing plate having an excellent image forming capability and having not only good hydrophilicity in a non-image part but also excellent printing resistance. Specifically, the present invention provides a lithographic printing plate precursor having a photosensitive layer containing a hydrophilic polymer, a crosslinking agent, hydrophobic polymer particles and a photo-thermal converter, wherein the hydrophilic polymer does not substantially contain, in its polymer chain, any of alcoholic hydroxyl groups and carboxyl groups (for example, 1.5% or less by mol of the repeating units of the hydrophilic polymer contain an alcoholic hydroxyl or carboxyl group).

### TECHNICAL FIELD

The present invention relates to a lithographic printing plate precursor and a resin composition for a photosensitive layer of the lithographic printing plate precursor.

### BACKGROUND ART

A lithographic printing plate is a printing plate used for lithographic printing and the surface of the lithographic printing plate contains an image part onto which ink is adhered and a non-image part which is ink-repellent and to which ink is not adhered. In general, the non-image part adsorbs and holds water. In order to print using the lithographic printing plate, water is first given to the non-image part so that the non-image part repels ink. Accordingly, the non-image part of the surface of the lithographic printing plate contains a hydrophilic material and the property of the hydrophilic material exerts a great influence on the performance of the lithographic printing plate.

The most common lithographic printing plate is a plate called a PS plate. The PS plate contains a support and a photosensitive layer coated on the support and the photosensitive layer on which light has been irradiated is developed to be used as a printing plate. However, in recent years, there have been vigorously made studies for the development of a lithographic printing plate precursor which requires no developing treatment from the viewpoint of environmental problems and the like.

The present applicants have proposed, as a lithographic printing plate precursor which requires no developing and no wiping operations, a lithographic printing plate precursor which contains a hydrophilic photosensitive layer obtained by crosslinking a resin composition for a photosensitive layer containing a hydrophilic polymer, a crosslinking agent, photo-thermal converter and a hydrophobic polymer and in which the photosensitive layer surface of the light-irradiated portion is changed from hydrophilicity to ink affinity (see Patent Documents 1 and 2).

A lithographic printing plate precursor, which is typified by the above Patent Documents 1 and 2 and utilizes the principle in which a photosensitive layer containing a hydrophilic resin is changed to ink affinity, has an extremely excellent performance. On the other hand, in the case of a lithographic printing plate obtained from the lithographic printing plate precursor specifically described in these Patent Documents, the hydrophilicity of the photosensitive layer in the non-image part is gradually deteriorated in the course of printing, sometimes causing scumming in the non-image part. Consequently, the improvement of further printing durability has been demanded.

For example, in Patent Document 2, there is specifically described a lithographic printing plate having a photosensitive layer using polyacrylamide as a hydrophilic polymer, but the image forming capability of the printing plate is not always sufficient and an accurate line may not be formed. The degree of the ink affinity in the image part is important in order to improve the image forming capability. A hydrophobic polymer is added to the photosensitive layer in order to increase the ink affinity, but the long-term durability of the hydrophilicity is decreased even by adding the hydrophobic polymer, possibly causing scumming.

Patent Document 1: International Publication No. WO2001/083234

### Patent Document 2: Japanese Patent Laid-Open Publication No. 2004-276277

### DISCLOSURE OF THE INVENTION

### Problems to be Solved by the Invention

Accordingly, an object of the present invention is to provide a precursor providing a lithographic printing plate which is excellent in image forming capability and has good hydrophilicity in a non-image part, as well as is excellent in printing resistance. Excellence in printing resistance includes the fact that the non-image part causes no scumming and the image part is unlikely to cause poor inking even in the case where the precursor is used for a long period of time. In addition, the present invention provides a resin composition for a photosensitive layer suitable for the production of such lithographic printing plate precursor.

### Means to Solve the Problems

The present inventors have found that these problems may be solved by designing a hydrophilic polymer contained in the photosensitive layer of the lithographic printing plate precursor so as to have a specific structure and completed the present invention.

In other words, the first of the present invention relates to the lithographic printing plate precursors described below.

[1] A lithographic printing plate precursor having a Photosensitive layer containing a hydrophilic polymer, a crosslinking agent, hydrophobic polymer particles and a photo-thermal converter, in which the hydrophilic polymer substantially does not contain, in its polymer chain, any of alcoholic hydroxyl groups and carboxyl groups.
[2] The lithographic printing plate precursor described in [1], in which 1.5% or less by mol of the repeating units of the hydrophilic polymer contain an alcoholic hydroxyl or carboxyl group.
[3] The lithographic printing plate precursor described in [1] or [2], in which the hydrophilic polymer contains at least one of the repeating units represented by the following general formulas (1) and (2).

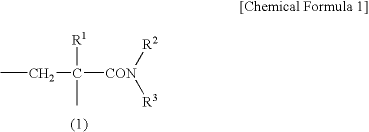

(In the formula (1), R¹ represents a hydrogen atom or a methyl group, R² and R³ each represents a hydrogen atom, a lower alkyl group or a lower alkoxy group, and R² and R³ may be the same or different from each other.)

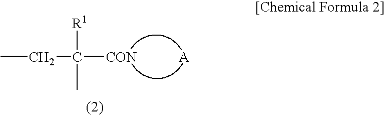

(In the formula (2), R¹ represents a hydrogen atom or a methyl group, and A represents (CH₂)ₙ (provided that n represents 4 to 6) or (CH₂)₂O(CH₂)₂.)
[4] The lithographic printing plate precursor layer described in any of [1] to [3], in which the hydrophilic polymer is a polymer of a monomer composition containing at least one of a compound represented by the following general formula (3) and a compound represented by the following general formula (4).

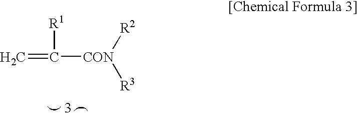

(In the formula (3), R¹ represents a hydrogen atom or a methyl group, R² and R³ each represents a hydrogen atom, a lower alkyl group or a lower alkoxy group, and R² and R³ may be the same or different from each other.)

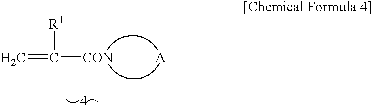

(In the formula (4), R¹ represents a hydrogen atom or a methyl group, and A represents (CH₂)ₙ (provided that n represents 4 to 6) or (CH₂)₂O(CH₂)₂.)
[5] The lithographic printing plate precursor described in any of [1] to [4], in which the content ratio of the hydrophilic polymer in the photosensitive layer is 20 to 60% by mass.

The second of the present invention relates to a resin composition for the photosensitive layer described below.

[6] A resin composition for a photosensitive layer of a lithographic printing plate precursor containing a hydrophilic polymer, a crosslinking agent, hydrophobic polymer particles, a photo-thermal converter and water, in which the hydrophilic polymer substantially does not contain, in its polymer chain, any of alcoholic hydroxyl groups and carboxyl groups.
[7] The resin composition for a photosensitive layer described in [6], in which 1.5% or less by mol of the repeating units of the hydrophilic polymer contain an alcoholic hydroxyl or carboxyl group.
[8] The resin composition for a photosensitive layer described in [6] or [7], in which the hydrophilic polymer contains at least one of the repeating units represented by the following general formulas (1) and (2).

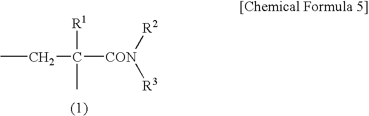

(In the formula (1), R¹ represents a hydrogen atom or a methyl group, R² and R³ each represents a hydrogen atom, a lower alkyl group or a lower alkoxy group, and R² and R³ may be the same or different from each other.)

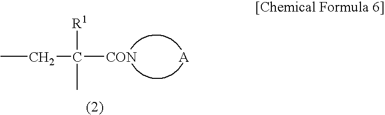

(In the formula (2), R¹ represents a hydrogen atom or a methyl group, and A represents (CH₂)ₙ (provided that n represents 4 to 6) or (CH₂)₂O(CH₂)₂.)
[9] The resin composition for a photosensitive layer described in any of [6] to [8], in which the hydrophilic polymer is a polymer of a monomer composition containing at least one of a compound represented by the following general formula (3) and a compound represented by the following general formula (4).

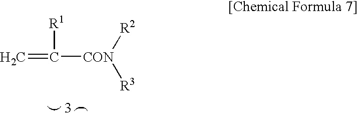

(In the formula (3), R¹ represents a hydrogen atom or a methyl group, R² and R³ each represents a hydrogen atom, a lower alkyl group or a lower alkoxy group, and R² and R³ may be the same or different from each other.)

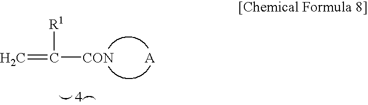

(In the formula (4), R¹ represents a hydrogen atom or a methyl group, and A represents (CH₂)ₙ (provided that n represents 4 to 6) or (CH₂)₂O(CH₂)₂.)
[10] The resin composition for a photosensitive layer described in any of [6] to [9], in which it contains at a ratio of 20 to 60 parts by mass of the hydrophilic polymer, 10 to 40 parts by mass of the crosslinking agent, 20 to 50 parts by mass of the hydrophobic polymer particles and 3 to 30 parts by mass of the photo-thermal converter.

The third of the present invention relates to a method of producing a lithographic printing plate precursor described below.

[11] A method of producing a lithographic printing plate precursor having a substrate and a photosensitive layer containing a hydrophilic polymer, a crosslinking agent, hydrophobic polymer particles and a photo-thermal converter; in which the method comprises a step of forming, on the substrate, a thin film containing the resin composition for a photosensitive layer described in any of [6] to [10].

### THE EFFECT OF THE INVENTION

According to the present invention, there may be provided a lithographic printing plate precursor excellent in printing resistance which is excellent in image forming capability and has good hydrophilicity in a non-image part, as well as causes no scumming in a non-image part and also causes no poor inking in an image part even in the case where the precursor is used for printing over a long period of time. By using the lithographic printing plate precursor of the present invention, a printing plate may be obtained in which processes such as developing and wiping are not required and which is excellent in image forming capability and printing resistance.

### BEST MODE FOR CARRYING OUT THE INVENTION

### 1. Regarding Resin Composition for Photosensitive Layer

A resin composition for a photosensitive layer of a lithographic printing plate precursor of the present invention contains (a) a hydrophilic polymer, (b) a crosslinking agent, (c) hydrophobic particles, (d) a photo-thermal converter and (e) water, and may contain (f) other components if desired.

(a) Hydrophilic Polymer

A hydrophilic polymer contained in a resin composition for a photosensitive layer of the present invention is characterized in that 1) at least part of the repeating units of the repeating units constituting the polymer has a hydrophilic group and 2) the polymer chain does not substantially contain alcoholic hydroxyl groups and carboxyl groups (hereinafter, the alcoholic hydroxyl or carboxyl group may be called an “OH group”). In addition, preferable is the hydrophilic polymer which exhibits no self-crosslinking property and is not structurally crystallized by a strong hydrogen bond. Further, the hydrophilic polymer is preferably dissolved in water in the resin composition for a photosensitive layer.

The hydrophilic polymer is a polymer which does not substantially contain OH group, but may contain an OH group in the range where the effect of the present invention is not impaired. That the polymer which does not substantially contain OH group means, for example, that among the repeating units constituting the hydrophilic polymer, the molar ratio of the repeating units containing an OH group is 1.5% or less by mol and preferably 1.0% or less by mol.

Among the repeating units, 1.5% or less by mol of the repeating units in the hydrophilic polymer may be the repeating units containing an OH group. And a hydrophilic polymer containing such an extremely small amount of the OH group may be obtained by copolymerizing a monomer containing an unsaturated compound having an OH group with a monomer composition containing other monomers.

Examples of the unsaturated compound having an OH group include a hydroxyalkyl(meth)acrylate such as hydroxyethyl(meth)acrylate, hydroxypropyl(meth)acrylate and hydroxybutyl(meth)acrylate; a polyalkyleneglycol mono(meth)acrylate such as polyethyleneglycol mono(meth)acrylate and polypropyleneglycol mono(meth)acrylate; methylol (meth) acrylamide; and the like. In addition, there are included a monobasic unsaturated acid such as (meth)acrylic acid; a dibasic unsaturated acid such as itaconic acid, fumaric acid, maleic acid and anhydride thereof; and a monoester or monoamide of these dibasic unsaturated acids. The term “(meth)acryl” may be interpreted to be either acryl or methacryl.

An unsaturated compound having two or more kinds of OH groups may be contained in a monomer composition to be copolymerized, so long as the total of the repeating units containing an OH group among the repeating units constituting a hydrophilic polymer is 1.5% or less by mol.

The molar ratio of the repeating units containing an OH group among the repeating units constituting a hydrophilic polymer contained in a resin composition for a photosensitive layer may be considered to be the content ratio of the monomer containing an OH group in the raw material monomer composition of the hydrophilic polymer; or may be estimated from the hydroxyl value or acid value of the hydrophilic polymer.

Since a hydrophilic polymer does not substantially contain alcoholic hydroxyl groups and carboxyl groups, the reaction with a crosslinking agent (described later) is unlikely to occur. For this reason, the degree of freedom of the polymer chain of the hydrophilic polymer is considered to increase in the formed photosensitive layer. Due to an increase in the degree of freedom of the polymer chain of the hydrophilic polymer, the photosensitive layer may be considered to exhibit more hydrophilicity. In other words, an ink stain adhered onto the plate surface may be rapidly removed and the sustained hydrophilic ability is achieved even in the course of printing.

As described above, a hydrophilic polymer contains a hydrophilic group in at least part of the repeating units of all repeating units constituting the polymer. Here, the term “at least part” means 90% or more by mol, preferably 95% or more by mol of the total repeating units and more preferably all the repeating units except for the repeating units containing an OH group.

Example of the hydrophilic group include an amide group, an amino group, a sulfone amide group, an oxymethylene group, oxyethylene group and the like, and preferable is a group represented by the following formula (X) or (Y).

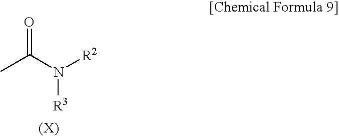

In the Formula (X), R² and R³ each represents a hydrogen atom and a lower alkyl group or a lower alkoxy group and may be the same or different from each other. The term “lower” means, for example, a group having 1 to 4 carbon atoms.

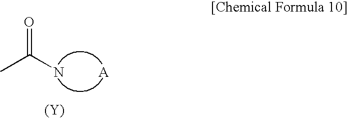

In the formula (Y), A represents (CH₂)ₙ (provided that n represents an integer of 4 to 6) or (CH₂)₂O(CH₂)₂.

Examples of the repeating unit containing a hydrophilic group include a repeating unit represented by the following general formulas (1) and (2).

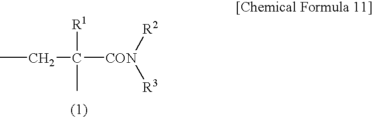

In the formula (1), R¹ represents a hydrogen atom or a methyl group, and R² and R³ each represents a hydrogen atom, a lower alkyl group or a lower alkoxy group. The term “lower” means, for example, a group having 1 to 4 carbon atoms.

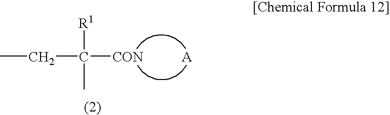

In the formula (2), R¹ represents a hydrogen atom or a methyl group, and A represents (CH₂)ₙ (provided that n represents an integer of 4 to 6) or (CH₂)₂O(CH₂)₂.

The hydrophilic polymer of the present invention preferably contains in its polymer main chain at least one of the repeating units represented by the general formulas (1) and (2). However, the hydrophilic polymer may be an addition polymerization type polymer or a condensation polymerization type polymer (for example, a polyamino acid, natural protein and the like).

The photosensitive layer, which is obtained from the resin composition containing a hydrophilic polymer containing at least one of the repeating units represented by the general formulas (1) and (2), may provide a lithographic printing plate precursor which is excellent in hydrophilicity and in which the non-image part is difficult to be stained and the stain once adhered to the plate surface is rapidly removed.

The hydrophilic polymer containing at least one of the repeating units represented by the general formulas (1) and (2) may be conveniently obtained by polymerizing or copolymerizing a monomer composition containing at least one of the compounds represented by the following general formulas (3) or (4).

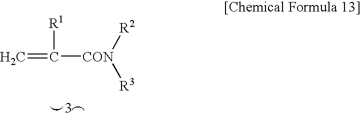

In the formula (3), R¹ represents a hydrogen atom or a methyl group, and R² and R³ each represents a hydrogen atom, a lower alkyl group or a lower alkoxy group and may the same or different from each other. The term “lower” means, for example, a group having 1 to 4 carbon atoms. Specific examples of the compound represented by the general formula (3) include acrylamide, methacrylamide, N-methyl(meth)acrylamide, N,N-dimethyl(meth)acrylamide and the like.

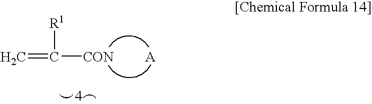

In the formula (4), R¹ represents a hydrogen atom or a methyl group, and A represents (CH₂)ₙ (provided that n represents an integer of 4 to 6) or (CH₂)₂O(CH₂)₂. Specific examples of the compound represented by the general formula (4) include N-acryloylmorpholine and the like.

More specific examples of the hydrophilic polymer include a polymer of a monomer composition mainly containing one or two or more kinds of compounds selected from acrylamide, methacrylamide, N-methyl(meth)acrylamide, N,N-dimethyl(meth)acrylamide, N-acryloylmorpholine and the like.

The hydrophilic polymer is especially preferably a polymer obtained by polymerizing acrylamide or copolymerizing acrylamide with other unsaturated monomers, and the molar ratio of the repeating units derived from acrylamide, among the repeating units constituting the hydrophilic polymer, is preferably 90% or more by mol and more preferably 95% or more by mol.

The hydrophilic polymer has a weight average molecular weight (Mw) of preferably ten thousand to twenty million and more preferably one hundred thousand to five million. When the weight average molecular weight (Mw) of the hydrophilic polymer is within the above range, the compatibility with other materials constituting the photosensitive layer (for example, hydrophobic polymer particles) is reduced, thereby preventing the occurrence of stain in the portion (for example, both end portions of the plate and portions having many images) in which the dampening solution supply is likely to be short during printing. In addition, since the viscosity of the resin composition for a photosensitive layer for forming a photosensitive layer may be suitably adjusted, a smooth photosensitive layer surface may be obtained by coating the resin composition for a photosensitive layer in the production of a precursor. In this way, the hydrophilic polymer preferably has a molecular weight in the above range so that the photosensitive layer exhibits good hydrophilicity.

The weight average molecular weight (Mw) is measured by, for example, gel permeation chromatography (GPC) and the like.

The content of the hydrophilic polymer in the resin composition for a photosensitive layer of the present invention is preferably 20 to 60% by mass and more preferably 25 to 50% by mass as a solid content. The term “solid content” means the components other than solvents (including water) contained in the resin composition. When the content of the hydrophilic polymer is within the above range, the hydrophilicity of the photosensitive layer to be formed is increased and an ink stain adhered onto the plate surface may be rapidly removed, and further the hydrophilicity is continuously maintained even in the course of printing. In addition, when the content of the hydrophilic polymer is within the above range, the hardness of the photosensitive layer formed is increased and the photosensitive layer is preferably prevented from dissolving in water.

(b) Crosslinking Agent

The crosslinking agent (hereinafter referred to as a “crosslinking agent in the present invention”) contained in the resin composition for the photosensitive layer of the present invention preferably has a self-crosslinking property. The term “self-crosslinking property” means a property which crosslinkable functional groups contained in a compound are reacted with each other to crosslink. In addition, the crosslinking agent is preferably dissolved in water in the resin composition for a photosensitive layer. The crosslinking agent in the present invention may be a compound having two or more crosslinkable functional groups per molecule and may preferably be a compound having three or more crosslinkable functional groups.

Examples of the crosslinking agent in the present invention include a compound having two or more epoxy groups, a compound having a methylol group and an imino group, and the like.

Examples of the compound having two or more epoxy groups include ethyleneglycol diglycidylether, polyethyleneglycol diglycidylether, propyleneglycol diglycidylether, polypropyleneglycol diglycidylether, sorbitol polyglycidyl ether, polyglycol polyglycidyl ether, glycerol polyglycidyl ether, polyglycerol polyglycidyl ether and the like. Examples of such commercially available compounds include epoxy compounds “Denacol™” series products manufactured by Nagase ChemteX Corp. and the like.

Examples of the compounds having a methylol group and an imino group include a methylated melamine resin, a phenol resin and the like. Examples of such commercially available compounds include melamine resins “Cymel™” series products manufactured by Nihon Cytec Industries Inc. and the like.

The content of the crosslinking agent in the resin composition for a photosensitive layer of the present invention is preferably 10 to 40% by mass and more preferably 10 to 30% by mass as a solid content. When the content of the crosslinking agent is within the above range, the photosensitive layer to be formed exhibits good hydrophilicity and the photosensitive layer may be prevented from dissolving in water during printing.

In the photosensitive layer of the lithographic printing plate precursor of the present invention, the crosslinking agents may be crosslinked with each other; or the crosslinking agent may be reacted with a hydrophilic polymer to crosslink the hydrophilic polymers. In either case, the photosensitive layer containing a hydrophilic polymer is preferably changed to water insoluble property by the crosslinking agent. Accordingly, it is possible to prevent that the photosensitive layer is dissolved in the dampening solution during printing and the photosensitive layer absorbs the dampening solution to decrease its strength, so that is possible to prevent the photosensitive layer from being scraped or peeled off by a blanket, ink or the like.

(c) Hydrophobic Polymer Particles

The hydrophobic polymer particles contained in the resin composition for a photosensitive layer of the present invention preferably are polymer particles which are insoluble in water and more preferably are hydrophobic polymer particles which are dispersed in water (hereinafter, also referred to as “aqueous dispersion hydrophobic polymer particles”).

The term “aqueous dispersion hydrophobic polymer particles” means hydrophobic fine polymer particles which are dispersed in an aqueous solvent. The aqueous solvent may contain a protective agent covering the particles when necessary. The aqueous dispersion hydrophobic polymer particles may be obtained by, for example, emulsion polymerizing or suspension polymerizing an unsaturated monomer. In addition, the aqueous dispersion hydrophobic polymer particles may be hydrophobic polymer particles which are dispersed in water and have an acidic group; may be hydrophobic polymer particles obtained by dispersing an organic solvent containing the hydrophobic polymer (in which the acidic group may be neutralized) in water (to which a dispersion stabilizer may be added); and may be hydrophobic polymer particles obtained by distilling off the organic solvent from the aqueous dispersion solution.

Specific examples of the aqueous dispersion hydrophobic polymer particles include an aqueous dispersion polyurethane resin, an aqueous dispersion polyester resin, an aqueous dispersion epoxy resin and the like, in addition to a latex such as a vinyl polymer latex, a conjugated dienepolymer latex and an acryl latex and the like.

The hydrophobic polymer particles may be dispersed in the hydrophilic polymer in the photosensitive layer. The hydrophobic polymer particles formed the island phase is melted and fused by the heat generated by converting light energy to thermal energy using a photo-thermal converter which absorbed light. By so doing, it is considered that the light irradiated part of the photosensitive layer surface is changed from hydrophobic to ink affinity.

The hydrophobic polymer particles have an average particle size of preferably 0.005 to 0.5 μm and more preferably 0.01 to 0.2 μm. If the particle size is within the above range, the hydrophobic polymer particles are readily melted and fused by the heat generated by light irradiation, resulting in a photosensitive layer having excellent sensitivity. The average particle size of the hydrophobic polymer particles is a weight average particle size, which may be measured by a dynamic light scattering and the like, for example, which may be measured by LPA 3100 manufactured by Otsuka Electronics Co., Ltd. and the like.

The content of the hydrophobic polymer particles in the resin composition for a photosensitive layer of the present invention is preferably 20 to 50% by mass and more preferably 25 to 45% by mass as a solid content. When the content of the hydrophobic polymer particles is within the above range, as mentioned above, the light irradiated part of the formed photosensitive layer has proper ink affinity. In addition, even in the case where it is used for printing over a long period of time, there is provided a printing plate which may carry out printing without causing the deterioration of the image part by scraping and the like. Further, if the content of the hydrophobic polymer particles is within the above range, the hydrophilic ability of a non-image part is good and there is a low possibility of causing scumming and the like.

Furthermore, if the content of the hydrophobic polymer particles is within the above range, the dispersion state of the hydrophobic polymer particles in the formed photosensitive layer is improved. That is, the hydrophobic polymer particles inhibit the excessive phase separation state between a hydrophilic polymer and a crosslinking agent to improve the dispersion state of the hydrophilic polymer.

(d) Photo-Thermal Converter

Examples of the photo-thermal converter contained in the resin composition for a photosensitive layer of the present invention include an infrared ray absorber (an agent having a property that absorbs infrared ray and converts it to heat) and the like. Specific examples of the infrared ray absorber include a cyanine dye, a phthalocyanine dye, a naphthalocyanine dye, carbon black, a metal oxide and the like, and preferable examples are a cyanine dye, a phthalocyanine dye, a naphthalocyanine dye and the like.

These photo-thermal converters preferably absorb light in a wavelength region of 750 to 1100 nm from the viewpoint of the handling property in a bright room, the output of a light source of an exposure machine for printing and the ease of use of the exposure machine. The absorption wavelength region of the photo-thermal converters may be adjusted by changing a substituent contained in the photo-thermal converters and the length of a n-electron-conjugated system as appropriate. The photo-thermal converter may be dissolved or dispersed in the resin composition for a photosensitive layer, but in either case, they preferably are hydrophilic.

The content of the photo-thermal converter in the resin composition for a photosensitive layer is preferably 3 to 30% by mass and more preferably 8 to 25% by mass as a solid content. When the content of the photo-thermal converter is within the above range, the hydrophilicity of the light irradiated surface of the photosensitive layer to be formed may be effectively changed to ink affinity.

(e) Water

The content of water in the resin composition for a photosensitive layer of the present invention is preferably 40 to 99% by mass and especially preferably 70 to 95% by mass. When the content of water is within the above range, the resin composition for a photosensitive layer is suitably coated on the substrate in the formation of the photosensitive layer and the film thickness of the photosensitive layer may be controlled with good accuracy.

(f) Other Components

A surfactant may be added to the resin composition for a photosensitive layer of the present invention in order to improve the adhesive property of water to a non-exposed part (a non-image part) of the photosensitive layer to be formed. The surfactant may be any one of an anionic surfactant, a cationic surfactant, a nonionic surfactant and an amphoteric surfactant, and they may be used alone or in combination with two or more kinds thereof. The addition amount of the surfactant is preferably 0.001 to 10% by mass and more preferably 0.01 to 5% by mass based on the hydrophilic polymer.

To the resin composition for a photosensitive layer may be added a repelling inhibitor and a leveling agent such as a perfluoroalkyl betaine and the like. In addition, the resin composition for a photosensitive layer may contain a filler for improving various properties of the photosensitive layer to be formed. The filler may be an organic-based or an inorganic-based one such as titanium oxide, silica and aluminum.

Further, the resin composition for a photosensitive layer may contain a low melting point compound and a degradable compound which are used to change the light irradiated part of the photosensitive layer from hydrophilicity to ink affinity (hydrophobicity) more easily. In addition, the resin composition for a photosensitive layer may contain various additives such as an antifoaming agent, a leveling agent and a coupling agent for the defoaming of the coated solution and for the smoothening of coated film.

The mass of the hydrophobic polymer particles in the resin composition for a photosensitive layer of the present invention is 30 to 50% relative to the total mass of the hydrophilic polymer, crosslinking agent and hydrophobic polymer particles; and the mass ratio of “the mass of the hydrophilic polymer/the crosslinking agent” is preferably approximately 1/2 to 3/1 and more preferably approximately 1/1 to 2/1. This is to improve the printing resistance by maintaining the ink affinity of the photosensitive layer by the hydrophobic polymer; and satisfying both the hydrophilicity by the hydrophilic polymer and the film strength by the crosslinking agent.

Further, the resin composition for a photosensitive layer of the present invention contains (a) 20 to 60 parts by mass of the hydrophilic polymer, (b) 10 to 40 parts by mass of the crosslinking agent, (c) 20 to 50 parts by mass of the hydrophobic polymer particles and (d) 3 to 30 parts by mass of the photo-thermal converter, and further preferably contains water.

### 2. Regarding Lithographic Printing Plate Precursor

The lithographic printing plate precursor of the present invention is characterized in that it has a photosensitive layer formed by using the resin composition for a photosensitive layer described above. The lithographic printing plate precursor of the present invention typically contains a substrate and a photosensitive layer formed on the substrate.

The formed photosensitive layer preferably contains (a) 20 to 60% by mass of the hydrophilic polymer, (b) 10 to 40% by mass of the crosslinking agent (crosslinked), (c) 20 to 50% by mass of the hydrophobic polymer particles and (d) 3 to 30% by mass of the photo-thermal converter. These content ratios may be determined by the ratio of each component in the resin composition for a photosensitive layer.

The content of (a) the hydrophilic polymer described above, in the photosensitive layer contained in the lithographic printing plate precursor, is preferably 20 to 60% by mass and more preferably 25 to 50% by mass. It is preferable that the hydrophilic polymer in the photosensitive layer is crosslinked by the crosslinking agent so as to be changed to be water-insoluble, or is changed to be water-insoluble by a crosslinking agent which is self-crosslinked. Needles to say, the crosslinking agent is self-crosslinked in the photosensitive layer or crosslinks the hydrophilic polymer.

The thickness of the photosensitive layer contained in the lithographic printing plate precursor is not particularly limited, but is typically approximately 0.1 to 10 μm and preferably approximately 0.5 to 3 μm.

The substrate contained in the lithographic printing plate precursor is not particularly limited, but may be a known substrate, and specifically there may be mentioned a metal plate such as an aluminum plate, steel plate, stainless plate and copper plate; a plastic film such as polyester, polyamide, polyethylene, polypropylene, polycarbonate and ABS resin; paper; aluminum foil laminated paper; metallized paper; plastic film laminated paper; and the like.

The thickness of the substrate is not particularly limited but typically is approximately 100 to 400 μm. In order to improve adherence properties, the substrate may be subjected to surface treatment such as oxidation treatment, chromate treatment, sandblast treatment and corona discharge treatment. In addition, in order to improve adhesion properties, the substrate may be provided with an underlayer (a primer layer).

The method of producing the lithographic printing plate precursor of the present invention is not particularly limited and includes a step of forming a thin film containing the resin composition for a photosensitive layer on the substrate. In addition, the method preferably includes a step of heating and drying the film formed.

The thin film containing the resin composition for a photosensitive layer is formed, for example, by coating the composition on the substrate. The coating means differ depending on the viscosity of the coating solution, the coating rate and the like and for example, there may be used a roll coater, blade coater, gravure coater, curtain flow coater or dye coater. In addition, the formation of the thin film containing the resin composition for a photosensitive layer may be carried out by spraying with a spray and the like.

The heating and drying of the formed thin film may be conducted typically at 50 to 200° C. It is considered that the crosslinking agent is self-crosslinked or crosslinks the hydrophilic polymer by heating.

The lithographic printing plate precursor of the present invention may be used as a non-development type precursor for off-set printing using a dampening solution. In that case, the light irradiated part of the photosensitive layer is an image part and a part except for the light irradiated part is a non-image part. Accordingly, the photosensitive layer is preferably hydrophilic and water-insoluble.

The lithographic printing plate precursor of the present invention is preferably irradiated by light in an absorption wavelength region (light in a wavelength region of 750 to 110 nm) of the photo-thermal converter contained in the photosensitive layer. By so doing, the photo-thermal converter contained in the photosensitive layer generates heat by absorbing light and the crosslinking agent and hydrophobic polymer generate foams and are thermally fused by the generated heat in the light irradiated part of the photosensitive layer, thereby the hydrophilicity of the light irradiated part loses and is changed to ink affinity (hydrophilicity).

The light irradiation to the lithographic printing plate precursor of the present invention is preferably scanned using the converging light at high speed from the viewpoint of the irradiation speed and the ease of use. In addition, a light source of high output is suitable for the irradiation. From these viewpoints, the light irradiated to the photosensitive layer of the precursor is preferably a laser beam and especially more preferably a laser beam having an oscillation wavelength in the wavelength region of from 750 to 1100 nm, and for example, preferable are a high-output laser diode having the wavelength of 830 nm and a YAG laser having the wavelength of 1064 nm. An exposure machine on which these lasers are mounted is already commercially available as a so-called thermal plate setter (an exposure machine).

In the lithographic printing plate thus obtained, since the hydrophilicity of the light irradiated part is changed to ink affinity (hydrophobicity) in the photosensitive layer, ink may adhere to the light irradiated part and printing may be carried out by using it without developing and wiping operations.

As described above, the printing plate obtained from the lithographic printing plate precursor of the present invention is 1) excellent in image forming capability, 2) has good hydrophilicity in a non-image part, 3) excellent in printing resistance because the non-image part causes no scumming and the image part is unlikely to cause poor inking even in the case where the printing is carried out over a long period of time. In addition, stain such as ink once adhered to the non-image part may be rapidly removed. These will be shown in Examples described below.

### EXAMPLES

Hereinafter, the present invention will be explained in more detail with reference to Examples and Comparative Examples, but the scope of the present invention is not restricted by these Examples.

In the following descriptions of Examples, “parts” represents “parts by mass” as a solid content of each resin or compound. Hereinafter, each component contained in the resin composition for a photosensitive layer is shown.

[Hydrophilic Polymer]

(1) Polyacrylamide: HOPELON™ H520B, Solid content: 20% by mass (manufactured by Mitsui Chemicals Inc.). OH group-containing monomer content: 0% by mol.

(2) Hydrophilic polymer P-1 to P-6: Refer to the Synthesis Examples described below).

[Crosslinking Agent]

Methylated Melamine Resin: Cymel™ 385, Solid content: 80% by mass (manufactured by ™Nihon Cytec Industries Inc.)

[Hydrophobic Polymer Particles]

(1) Urethane Fine Particles: Emulsion OLESTER™ UD350, Solid content: 40% by mass (manufactured by Mitsui Chemicals Inc.). The weight average particle size of urethane fine particles UD350 measured by a dynamic light scattering (LPA 3100: manufactured by Otsuka Electronics Co., Ltd.) was 0.03 μm.

(2) Urethane Fine Particles: Emulsion OLESTER™ UD500, Solid content: 40% by mass (manufactured by Mitsui Chemicals Inc.). The weight average particle size of urethane fine particles UD500 measured by a dynamic light scattering (LPA 3100: manufactured by Otsuka Electronics Co., Ltd.) was 0.09 μm.

[Photo-Thermal Converter]

Cyanine Dye: λmax is 784 nm and εmax is 2.43×10⁵ Lmol⁻¹cm⁻¹ in a methanol solution. The solid content is 5% by mass.

[Surfactant]

(1) Anionic Surfactant: Neocol™ YSK, Solid content: 100% by mass (manufactured by Dai-Ichi Kogyo Seiyaku Co., Ltd.)

(2) Perfluoroalkyl Betaine: Surflon™ S-131, Solid content: 30% by mass (manufactured by Seimi Chemical Co., Ltd.)

[Synthesis of Hydrophilic Polymer P-1]

After the removal of dissolved oxygen by bubbling nitrogen, 335 g of purified water charged in a flask was heated to 80° C. While nitrogen gas was blown into the flask, to the flask, an initiator/a monomer aqueous solution containing 74.25 g of acrylamide, 75 g of purified water, 0.75 g of sodium metallylsulfonate and 0.75 g of potassium persulfate was continuously added dropwise over 2 hours, maintaining the internal temperature at 80° C. After the completion of the dropwise addition, polymerization was continued for 3 hours at 80° C., followed by cooling to take out a polymerization solution from the flask. The resulting polymerization solution had a solid content of 15% by mass. The resulting hydrophilic polymer P-1 had a molecular weight Mw of 390000. The content ratio of the repeating units each having an OH group of the hydrophilic polymer P-1 is 0% by mol.

[Synthesis of Hydrophilic Polymer P-2]

After the removal of dissolved oxygen by bubbling nitrogen, 335 g of purified water charged in a flask was heated to 80° C. While nitrogen gas was blown into the flask, to the flask, an initiator/a monomer aqueous solution containing 67.5 g of acrylamide, 7.5 g of N,N-dimethylmethacrylamide, 75 g of purified water and 0.75 g of potassium persulfate was continuously added dropwise over 2 hours, maintaining the internal temperature at 80° C. After the completion of the dropwise addition, polymerization was continued for 3 hours at 80° C., followed by cooling to take out a polymerization solution from the flask. The resulting polymerization solution had a solid content of 15% by mass. The resulting hydrophilic polymer P-2 had a molecular weight Mw of 410000. The content ratio of the repeating units each having an OH group of the hydrophilic polymer P-2 is 0% by mol.

[Synthesis of Hydrophilic Polymer P-3]

After the removal of dissolved oxygen by bubbling nitrogen, 335 g of purified water charged in a flask was heated to 80° C. While nitrogen gas was blown into the flask, to the flask, an initiator/a monomer aqueous solution containing 67.5 g of acrylamide, 7.5 g of acryloylmorpholine, 75 g of purified water and 0.75 g of potassium persulfate was continuously added dropwise over 2 hours, maintaining the internal temperature at 80° C. After the completion of the dropwise addition, polymerization was continued for 3 hours at 80° C., followed by cooling to take out a polymerization solution from the flask. The resulting polymerization solution had a solid content of 15% by mass. The resulting hydrophilic polymer P-3 had a molecular weight Mw of 340000. The content ratio of the repeating units each having an OH group of the hydrophilic polymer P-3 is 0% by mol.

[Synthesis of Hydrophilic Polymer P-4]

After the removal of dissolved oxygen by bubbling nitrogen, 335 g of purified water charged in a flask was heated to 80° C. While nitrogen gas was blown into the flask, to the flask, a monomer solution containing 63.75 g of acrylamide, 11.25 g of 2-hydroxyethylmethacrylate and 300 g of purified water and an initiator aqueous solution in which 0.225 g of potassium persulfate is dissolved in 40 g of purified water were continuously and separately added dropwise over 2 hours, maintaining the internal temperature at 80° C. After the completion of the dropwise addition, polymerization was continued for 3 hours at 80° C., followed by cooling to take out a polymerization solution from the flask. The resulting polymerization solution had a solid content (hydrophilic polymer P-4) of 10% by mass. The resulting hydrophilic polymer P-4 had a molecular weight Mw of 600000. The content of the OH group-containing monomer in the raw material monomer composition of the hydrophilic polymer P-4 is 9% by mol.

[Synthesis of Hydrophilic Polymer P-5]

After the removal of dissolved oxygen by bubbling nitrogen, 335 g of purified water charged in a flask was heated to 80° C. While nitrogen gas was blown into the flask, to the flask, a monomer solution containing 72.75 g of acrylamide, 2.25 g of 2-hydroxyethylmethacrylate and 300 g of purified water and an initiator aqueous solution in which 0.225 g of potassium persulfate is dissolved in 40 g of purified water were continuously and separately added dropwise over 2 hours, maintaining the internal temperature at 80° C. After the completion of the dropwise addition, polymerization was continued for 3 hours at 80° C., followed by cooling to take out a polymerization solution from the flask. The resulting polymerization solution had a solid content (hydrophilic polymer P-5) of 10% by mass. The resulting hydrophilic polymer P-5 had a molecular weight Mw of 640000. The content of the OH group-containing monomer in the raw material monomer composition of the hydrophilic polymer P-5 is 1.7% by mol.

[Synthesis of Hydrophilic Polymer P-6]

After the removal of dissolved oxygen by bubbling nitrogen, 335 g of purified water charged in a flask was heated to 80° C. While nitrogen gas was blown into the flask, to the flask, a monomer solution containing 73.5 g of acrylamide, 1.5 g of 2-hydroxyethylmethacrylate and 300 g of purified water and an initiator aqueous solution in which 0.225 g of potassium persulfate is dissolved in 40 g of purified water were continuously and separately added dropwise over 2 hours, maintaining the internal temperature at 80° C. After the completion of the dropwise addition, polymerization was continued for 3 hours at 80° C., followed by cooling to take out a polymerization solution from the flask. The resulting polymerization solution had a solid content (hydrophilic polymer P-6) of 10% by mass. The content of the OH group-containing monomer in the raw material monomer composition of the hydrophilic polymer P-6 is 1.1% by mol.

A hydrophilic polymer, a crosslinking agent, hydrophobic polymer particles, a photo-thermal converter and a surfactant were mixed at room temperature in the composition shown in Table 1 to obtain the resin composition for a photosensitive layer used in Examples 1 to 6.

TABLE 1

| | Hydrophilic | | Hydrophobic | | | | | |
|---|---|---|---|---|---|---|---|---|
| | Polymer (1) | Crosslinking | Polymer Particles | | Photo-thermal | Surfactant | | |
| | Polyacrylamide | Agent | (1) | (2) | Converter | (1) | | (2) |
| Example 1 | 40 parts | 25 parts | 35 parts | | 15 parts | 2.5 | parts | 0.25 part |
| Example 2 | 35 parts | 30 parts | 35 parts | | 12 parts | 2.5 | parts | 0.25 part |
| Example 3 | 45 parts | 20 parts | | 35 parts | 15 parts | 5 | parts | 0.25 part |
| Example 4 | 55 parts | 15 parts | 30 parts | | 18 parts | 5 | parts | 0.25 part |
| Example 5 | 40 parts | 15 parts | 45 parts | | 12 parts | 1 | part | 0.25 part |
| Example 6 | 35 parts | 25 parts | 40 parts | | 15 parts | 3 | parts | 0.25 part |

### Example 1

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 180° C. for 10 minutes to form a film of an underlayer. The resin composition for a photosensitive layer shown in Table 1 was coated on the formed underlayer using a wire bar and then dried at 170° C. for 20 minutes, followed by forming a film of a photosensitive layer having a film thickness of approximately 2 μm to produce a lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 270 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. In addition, the ink stain adhered especially to the non-image part on the blanket was not confirmed.

### Example 2

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 180° C. for 10 minutes to form a film of an underlayer. The resin composition for a photosensitive layer shown in Table 1 was coated on the formed underlayer using a wire bar and then dried at 160° C. for 30 minutes, followed by forming a film of a photosensitive layer having a film thickness of approximately 2 μm to produce a lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 300 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. In addition, the ink stain adhered especially to the non-image part on the blanket was not confirmed.

### Example 3

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 140° C. for 10 minutes to form a film of an underlayer. The resin composition for a photosensitive layer shown in Table 1 was coated on the formed underlayer using a wire bar and then dried at 160° C. for 20 minutes, followed by forming a film of a photosensitive layer having a film thickness of approximately 2 μm to produce a lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 300 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. In addition, the ink stain adhered especially to the non-image part on the blanket was not confirmed.

### Example 4

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 140° C. for 10 minutes to form a film of an underlayer. The resin composition for a photosensitive layer shown in Table 1 was coated on the formed underlayer using a wire bar and then dried at 185° C. for 15 minutes, followed by forming a film of a photosensitive layer having a film thickness of approximately 2 μm to produce a lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 300 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. In addition, the ink stain adhered especially to the non-image part on the blanket was not confirmed.

### Example 5

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 140° C. for 10 minutes to form a film of an underlayer. The resin composition for a photosensitive layer shown in Table 1 was coated on the formed underlayer using a wire bar and then dried at 150° C. for 20 minutes, followed by forming a film of a photosensitive layer having a film thickness of approximately 2 μm to produce a lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 270 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. In addition, the ink stain adhered especially to the non-image part on the blanket was not confirmed.

### Example 6

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 140° C. for 10 minutes to form a film of an underlayer. The resin composition for a photosensitive layer shown in Table 1 was coated on the formed underlayer using a wire bar and then dried at 170° C. for 20 minutes, followed by forming a film of a photosensitive layer having a film thickness of approximately 2 μm to produce a lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 270 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. In addition, the ink stain adhered especially to the non-image part on the blanket was not confirmed.

A hydrophilic polymer, a crosslinking agent, hydrophobic polymer particles, a photo-thermal converter and a surfactant were mixed at room temperature in the composition shown in Table 2 to obtain the resin composition for a photosensitive layer used in Examples 7 to 12.

TABLE 2

| | | | Hydrophobic | | | | | |
|---|---|---|---|---|---|---|---|---|
| | Hydrophilic | Crosslinking | Polymer | Photo-thermal | Surfactant | | | |
| | Polymer | Agent | Particles(1) | Converter | (1) | | (2) | |
| Example 7 | P-1: 35 parts | 25 parts | 40 parts | 15 parts | 2 | parts | 0.25 | part |
| Example 8 | P-2: 35 parts | 25 parts | 40 parts | 12 parts | 1.5 | parts | 0.2 | part |
| Example 9 | P-3: 45 parts | 25 parts | 40 parts | 14 parts | 2 | parts | 0.25 | part |
| Example 10 | P-6: 35 parts | 35 parts | 30 parts | 12 parts | 2.5 | parts | 0.05 | part |
| Example 11 | Polyacrylamide: | 25 parts | 45 parts | 12 parts | 5 | parts | 0.25 | part |
| | 30 parts | | | | | | | |
| Example 12 | Polyacrylamide: | 35 parts | 45 parts | 12 parts | 1.5 | parts | 0.15 | part |
| | 20 parts | | | | | | | |

### Example 7

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 140° C. for 10 minutes to form a film of an underlayer. The resin composition for a photosensitive layer shown in Table 2 was coated on the formed underlayer using a wire bar and then dried at 170° C. for 20 minutes, followed by forming a film of a photosensitive layer having a film thickness of approximately 2 μm to produce a non-development lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 270 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. In addition, the ink stain adhered especially to the non-image part on the blanket was not confirmed.

### Example 8

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 140° C. for 10 minutes to form a film of an underlayer. The resin composition for a photosensitive layer shown in Table 2 was coated on the formed underlayer using a wire bar and then dried at 165° C. for 20 minutes, followed by forming a film of a photosensitive layer having a film thickness of approximately 2 μm to produce a non-development lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 300 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. However, a little stain was observed on the blanket of the present Example as compared to the state of the blanket of Examples 1 to 7.

### Example 9

### Production of Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 140° C. for 10 minutes to form a film of an underlayer. The resin composition for a photosensitive layer shown in Table 2 was coated on the formed underlayer using a wire bar and then dried at 175° C. for 20 minutes, followed by forming a film of a photosensitive layer having a film thickness of approximately 2 μm to produce a non-development lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 300 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 50 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. However, a little stain was observed on the blanket of the present Example and the stain was as the same level as in Example 8, as compared to the state of the blanket of Examples 1 to 7.

### Example 10

### Production of Lithographic Printing Plate Precursor and Production of Drawing and Lithographic Printing Plate

A lithographic printing plate precursor and a drawing and lithographic printing plate was produced in a similar manner to Example 1 except that the coated photosensitive resin composition was changed to the composition shown in Table 2.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 200 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. However, a little stain was observed on the blanket of the present Example as compared to the state of the blanket of Examples 1 to 7.

### Example 11

### Production of Non-Development Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 140° C. for 10 minutes to form a film of an underlayer. Next, a photosensitive resin composition containing the composition shown in Table 2 was coated on the underlayer using a wire bar and then dried at 160° C. for 30 minutes, followed by forming a film of a photosensitive layer having a film thickness of approximately 2 μm to produce a non-development lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 300 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 200 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. However, a little stain was observed on the blanket of the present Example as compared to the state of the blanket of Examples 1 to 7.

### Example 12

### Production of Non-Development Lithographic Printing Plate Precursor

An aqueous dispersion of an urethane resin (OLESTER™ UD350 having a solid content of 40% by mass, manufactured by Mitsui Chemicals Inc.) was coated using a wire bar on an aluminum plate with a thickness of 0.24 mm, followed by drying at 150° C. for 10 minutes to form a film of an underlayer. Next, a photosensitive resin composition containing the composition shown in Table 2 was coated on the formed underlayer using a wire bar and then dried at 155° C. for 30 minutes, followed by forming a film of a photosensitive layer having a film thickness of approximately 2 μm to produce a non-development lithographic printing plate precursor.

### <Production of Drawing and Lithographic Printing Plate>

The resulting precursor was scanning-irradiated with a laser diode beam having a wavelength of 830 nm with collimating the beam so that the irradiation energy density became 300 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. The ink was (purposely) adhered onto the precursor surface by bringing the ink roller into contact with the precursor surface before starting the printing, and thereafter the printing was started. While 200 sheets of print material were trial-printed, the ink roller-shaped ink stain adhered to the precursor was removed, thereby providing a good printed material. When fifty thousand sheets of print material were directly printed and the fifty thousandth sheet was confirmed, it was confirmed that the sheet had no stain in the non-image part, a good ink fixing property in the image part and a good printing resistance. However, a little stain was observed on the blanket of the present Example as compared to the state of the blanket of Examples 1 to 7.

A hydrophilic polymer, a crosslinking agent, hydrophobic polymer particles, a photo-thermal converter and a surfactant were mixed at room temperature in the composition shown in able 3 to obtain the resin composition for a photosensitive layer used in Comparative Examples 1 to 5.

TABLE 3

| | | | Hydrophobic | | | | | |
|---|---|---|---|---|---|---|---|---|
| | Hydrophilic | Crosslinking | Polymer | | Photo-thermal | Surfactant | | |
| | Polymer | Agent | Particles(1) | | Converter | (1) | | (2) |
| Comparative | P-4: 35 parts | 35 parts | 30 | part | 12 parts | 1 | part | 0.05 part |
| Example 1 | | | | | | | | |
| Comparative | P-5: 35 parts | 35 parts | 30 | parts | 12 parts | 2.5 | parts | 0.05 part |
| Example 2 | | | | | | | | |
| Comparative | P-4: 65 parts | 35 parts | 0 | part | 15 parts | 3 | parts | 0.25 part |
| Example 3 | | | | | | | | |
| Comparative | Polyacrylamide: | 40 parts | 0 | part | 15 parts | 3 | parts | 0.25 part |
| Examples 4 And 5 | 60 parts | | | | | | | |

### Comparative Example 1

### Production of Lithographic Printing Plate Precursor and Production of Drawing and Lithographic Printing Plate

A non-development lithographic printing plate precursor and a drawing and lithographic printing plate were produced in a similar manner to Example 1 except that the resin composition for the photosensitive layer coated was changed to the composition shown in Table 3.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. A good printed material was obtained at the beginning of the printing, but when fifty thousand sheets of print material were printed and the fifty thousandth sheet was confirmed, the occurrence of scumming in the non-image part was confirmed. In addition, ink stain was severely adhered to the non-image part on the blanket.

Further, the precursor drawn in a similar manner was set in a similar printer and the ink was (purposely) adhered onto the precursor surface by bringing the ink roller into contact with the precursor surface before starting the printing, and thereafter the printing was started using an ink and dampening solution with the same conditions. Even after trial printing of 200 sheets, the ink roller-shaped ink stain adhered to the precursor was not completely removed.

### Comparative Example 2

### Production of Lithographic Printing Plate Precursor and Production of Drawing and Lithographic Printing Plate

A lithographic printing plate precursor and a drawing and lithographic printing plate were produced in a similar manner to Example 1 except that the resin composition for a photosensitive layer coated was changed to the composition shown in Table 3.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. A good printed material was obtained at the beginning of the printing, but when the fifty thousandth sheet was confirmed, the occurrence of scumming in the non-image part was confirmed. In addition, ink stain was severely adhered to the non-image part on the blanket.

Further, the precursor drawn in a similar manner was set in a similar printer and the ink was (purposely) adhered onto the precursor surface by bringing the ink roller into contact with the precursor surface before starting the printing, and thereafter the printing was started using an ink and dampening solution with the same conditions. Even after trial printing of 200 sheets, the ink roller-shaped ink stain adhered to the precursor was not completely removed.

### Comparative Example 3

### Production of Lithographic Printing Plate Precursor

A lithographic printing plate precursor was produced in a similar manner to Example 1 except that the resin composition for a photosensitive layer coated was changed to the composition shown in Table 3.

### <Production of Drawing and Lithographic Printing Plate>

The resulting precursor was scanning-irradiated with a laser diode beam having a wavelength of 830 nm with collimating the beam so that the irradiation energy density became 500 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. A good printed material was obtained at the beginning of the printing, but when the fifty thousandth sheet was confirmed, it was not a good printing material because the occurrence of scumming in the non-image part was confirmed and poor inking occurred in most of the image part. In addition, ink stain was severely adhered to the non-image part on the blanket.

Further, the precursor drawn in a similar manner was set in a similar printer and the ink was (purposely) adhered onto the precursor surface by bringing the ink roller into contact with the precursor surface before starting the printing, and thereafter the printing was started using an ink and dampening solution with the same conditions. Even after trial printing of 200 sheets, the ink roller-shaped ink stain adhered to the precursor was not completely removed.

### Comparative Example 4

### Production of Lithographic Printing Plate Precursor

A lithographic printing plate precursor was produced in a similar manner to Example 1 except that the resin composition for a photosensitive layer coated was changed to the composition shown in Table 3.

### <Production of Drawing and Lithographic Printing Plate>

The resulting precursor was scanning-irradiated with a laser diode beam having a wavelength of 830 nm with collimating the beam so that the irradiation energy density became 500 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. A good printed material was not obtained from the beginning of the printing because of poor inking on the image part. In addition, when twenty thousand sheets of print material were printed and the twenty thousandth sheet was confirmed, the occurrence of scumming on the printed material was observed. Further, ink stain was severely adhered on the blanket.

Furthermore, the precursor drawn in a similar manner was set in a similar printer and the ink was (purposely) adhered onto the precursor surface by bringing the ink roller into contact with the precursor surface before starting the printing, and thereafter the printing was started using an ink and dampening solution with the same conditions. Even after trial printing of 200 sheets, the ink roller-shaped ink stain adhered to the precursor was not completely removed.

### Comparative Example 5

### Production of Draw and Lithographic Printing Plate of Lithographic Printing Plate Precursor

The lithographic printing plate precursor produced in Comparative Example 4 was scanning-irradiated with a laser diode beam having a wavelength of 830 nm with collimating the beam so that the irradiation energy density became 270 mJ/cm², thereby carrying out drawing of imagery information of 175 lines/inch.

### <Printing Evaluation>

The drawn precursor was set in an offset printer (SPRI NT 26 manufactured by Komori Corporation) using a dampening solution and printing was carried out using TK High Unity MZ (manufactured by Toyo Ink Mfg. Co., Ltd) as an ink and a 1.5% aqueous solution of Fountain Solution Astromark 3 (manufactured by Nikken Chemicals Co., Ltd.) as a dampening solution. A good printed material was not obtained from the beginning of the printing because of poor inking on the image part. In addition, the inking state of the image part of the present Comparative Example was further deteriorated as compared with Comparative Example 4. And, when the twenty thousandth sheet was confirmed, the occurrence of scumming on the printed material was observed. Further, ink stain was severely adhered also on the blanket.

Furthermore, the precursor drawn in a similar manner was set in a similar printer and the ink was (purposely) adhered on the precursor surface by bringing the ink roller into contact with the precursor surface before starting the printing, and thereafter the printing was started using an ink and dampening solution with the same conditions. Even after trial printing of 200 sheets, the ink roller-shaped ink stain adhered to the precursor was not completely removed.

### INDUSTRIAL APPLICABILITY

The resin composition for a photosensitive layer of the present invention is used for the production of a lithographic printing plate precursor which requires no developing and wiping operations and there may be obtained from the precursor a lithographic printing plate which is excellent in hydrophilicity of an non-image part and ink affinity of an image part as well as excellent in printing resistance.

The present application claims priority based on Application No. JP 2005-248662 filed on Aug. 30, 2005, the entirety of which is incorporated herein by reference.

1. A lithographic printing plate precursor having a photosensitive layer containing a hydrophilic polymer, a crosslinking agent, hydrophobic polymer particles and a photo-thermal converter, wherein the hydrophilic polymer does not substantially contain, in its polymer chain, any of alcoholic hydroxyl groups and carboxyl groups.

2. The lithographic printing plate precursor according to claim 1, wherein 1.5% or less by mol of the repeating units of the hydrophilic polymer contain an alcoholic hydroxyl or carboxyl group.

3. The lithographic printing plate precursor according to claim 1, wherein the hydrophilic polymer contains at least one of the repeating units represented by the following general formulas (1) and (2); 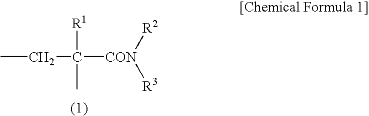
wherein
R¹ represents a hydrogen atom or a methyl group,
R² and R³ each represents a hydrogen atom, a lower alkyl group or a lower alkoxy group, and R² and R³ may be the same or different from each other; 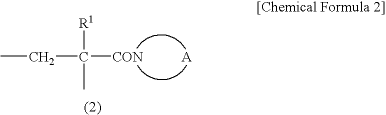
wherein
R¹ represents a hydrogen atom or a methyl group, and
A represents (CH₂)ₙ (provided that n represents 4 to 6) or (CH₂)₂O(CH₂)₂.

4. The lithographic printing plate precursor according to claim 1, wherein the hydrophilic polymer is a polymer of a monomer composition containing at least one of a compound represented by the following general formula (3) and a compound represented by the following general formula (4); 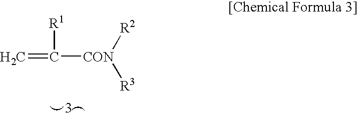
wherein
R¹ represents a hydrogen atom or a methyl group,
R² and R³ each represents a hydrogen atom, a lower alkyl group or a lower alkoxy group, and R² and R³ may be the same or different from each other; 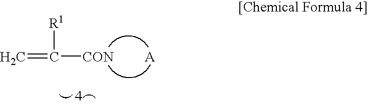
wherein
R¹ represents a hydrogen atom or a methyl group, and
A represents (CH₂)ₙ (provided that n represents an integer of 4 to 6) or (CH₂)₂O(CH₂)₂.

5. The lithographic printing plate precursor according to claim 1, wherein the content ratio of the hydrophilic polymer in the photosensitive layer is 20 to 60% by mass.

6. A resin composition for a photosensitive layer of a lithographic printing plate precursor containing a hydrophilic polymer, a crosslinking agent, hydrophobic polymer particles, a photo-thermal converter and water, wherein the hydrophilic polymer does not substantially contain, in its polymer chain, any of alcoholic hydroxyl groups and carboxyl groups.

7. The resin composition for a photosensitive layer according to claim 6, wherein 1.5% or less by mol of the repeating units of the hydrophilic polymer contain an alcoholic hydroxyl or carboxyl group.

8. The resin composition for a photosensitive layer according to claim 6, wherein the hydrophilic polymer contains at least one of the repeating units represented by the following general formulas (1) and (2) 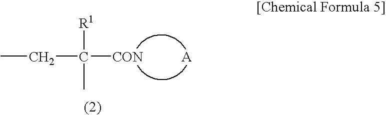
wherein
R¹ represents a hydrogen atom or a methyl group, R² and R³ each represents a hydrogen atom, a lower alkyl group or a lower alkoxy group, and R² and R³ may be the same or different from each other; 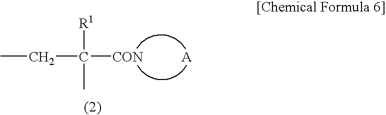
wherein
R¹ represents a hydrogen atom or a methyl group, and
A represents (CH₂)ₙ (provided that n represents 4 to 6) or (CH₂)₂O(CH₂)₂.

9. The resin composition for a photosensitive layer according to claim 6, wherein the hydrophilic polymer is a polymer of a monomer composition containing at least one of a compound represented by the following general formula (3) and a compound represented by the following general formula (4); 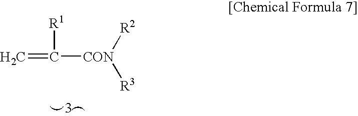
wherein
R¹ represents a hydrogen atom or a methyl group,
R² and R³ each represents a hydrogen atom, a lower alkyl group or a lower alkoxy group, and R² and R³ may be the same or different from each other; 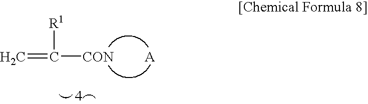
wherein
R¹ represents a hydrogen atom or a methyl group, and
A represents (CH₂)ₙ (provided that n represents an integer of 4 to 6) or (CH₂)₂O(CH₂)₂.

10. The resin composition for a photosensitive layer according to claim 6, comprising the hydrophilic polymer at a ratio of 20 to 60 parts by mass, the crosslinking agent at a ratio of 10 to 40 parts by mass, the hydrophobic polymer particles at a ratio of 20 to 50 parts by mass and the photo-thermal converter at a ratio of 3 to 30 parts by mass.

11. A method of producing a lithographic printing plate precursor having a substrate and a photosensitive layer containing a hydrophilic polymer, a crosslinking agent, hydrophobic polymer particle and a photo-thermal converter; comprising a step of forming, on the substrate, a thin film containing the resin composition for a photosensitive layer according to claim 6.
